(19) United States
(12) Patent Application Publication
(10) Pub. No.: US 2020/0035718 A1
(43) Pub. Date: Jan. 30, 2020

(54) AN INTERLAYER-DIELECTRIC LAYER, A MANUFACTURING METHOD THEREOF, AND A LIQUID CRYSTAL DISPLAY PANEL

(71) Applicant: Wuhan China Star Optoelectronics Technology Co., Ltd, Wuhan , Hubei (CH)

(72) Inventor: Rui LU, Wuhan, Hubei (CN)

(21) Appl. No.: 15/735,547

(22) PCT Filed: Oct. 12, 2017
(86) PCT No.: PCT/CN2017/105830

§ 371 Date: Dec. 11, 2017

(30) Foreign Application Priority Data
Sep. 19, 2017 (CN) 201710846716.7

(51) Int. Cl. H01L 27/12; H01L 21/02; G02F 1/1333; C23C 16/34

(52) U.S. Cl. CPC H01L 27/1248; H01L 21/0217; H01L 21/02164; G02F 1/1368; G02F 1/133345; H01L 27/1262; C23C 16/345; H01L 21/02271

(57) ABSTRACT

The present disclosure provides an interlayer-dielectric (ILD) layer, a manufacturing method thereof, and a liquid crystal display panel. The manufacturing method includes the steps of: S1, sequentially depositing a first SiNx layer having low refractive index and a second SiNx layer having high refractive index on a substrate, wherein the range of the low refractive index is 1.7˜1.87, the range of the high refractive index is 1.91˜1.93, and x [symbol] 1; S2, depositing a SiOy layer on the second SiNx layer, wherein the refractive index range of the SiOy layer is 1.4˜1.5, and y [symbol] 1. The ILD layer of the present disclosure has better elasticity and stability and bears smaller stress so it does not damage the film to form the broken film or peeling of the film and reduces influence on the long-distance accuracy of the low-temperature polysilicon.

### RELATED APPLICATIONS

The present application is a National Phase of International Application Number PCT/CN2017/105830, filed Oct. 12, 2017, and claims the priority of China Application No. 201710846716.7, filed Sep. 19, 2017.

### FIELD OF THE DISCLOSURE

The present disclosure relates to liquid crystal display field, and more particularly, to an interlayer-dielectric layer, a manufacturing method thereof, and a liquid crystal display panel.

### BACKGROUND

In the chemical vapor deposition (CVD) process of low temperature polysilicon (LTPS), an interlayer-dielectric (ILD) layer is designed to be between a SiN layer and a SiO layer. The thickness of the SiN layer and the SiO layer are both 300 nm. The art is as follows:

(1) An ILD layer of 600 nm thick is deposited on a glass completing a preprocess. There are two steps to form a film. A first step includes depositing a 300 nm SIN layer, a second step includes depositing a 300 nm SIO layer, and the total thickness of the ILD layer is 600 nm.

(2) After the ILD layer is deposited, the ionization and hydrogenation (RTA) treatment of the implantation of the film is conducted to repair the dangling bond of the polysilicon, and then the whole ILD layer process is completed by exposure, wet etching, and photoresist stripping process.

(3) Following process.

In the art of low-temperature polysilicon, when the ILD layer is prepared, the 300 nm SIN layer is deposited and the 300 nm SIO layer is deposited then, and the refractive index (N value) of the SIN layer is about 1.90, and the N value of the SIO is about 1.45. This design has the problems below:

(1) Stability problem: The N value reflects the composition and compactness of the film, and further reflects the stress of the film. If the N value is high, the corresponding film has stronger hydrogen capacity; and if the N value is low, the corresponding film has better elasticity and the stability is good. The SIN layer with higher N value directly contacts with the glass completing the preprocess and the elasticity of the film is poor so there are some problems such as bubbles occur between the SIN layer and the glass and the device is unstable.

(2) Film problem: N value reflects the stress of the film. The film suffers from different stresses and is broken: Compressive stress damages the film and tensile stress breaks the film. N value of the SIN layer is higher so when the film accepts stress, the film structure is damaged and the film is peeling.

(3) TTP problem: Preparation of the ILD layer is a high-temperature process such as 380° C. high temperature. The high temperature results in thermal expansion and contraction effect of the ILD layer and various degrees of contraction of the glass substrate. It affects long-distance accuracy (That is, it affects the accuracy of the long-distance measurement mark on low-temperature polysilicon layer. The long-distance measurement mark is for the post process. The array circuit on the ILD layer aligns with the finger alignment mark on the filter, and the corresponding deformation of the finger alignment mark is monitored. If the deformation can be accurately measured, the deformation can be controlled and paste accuracy of the array circuit and filter can be determined). It further affects the paste accuracy of the array circuit and finger alignment mark the, and reduces the alignment accuracy of the array circuit with the filter. In addition, stress of the ILD layer is different and the ILD layer presents different contractions. The SIN film of the ILD layer is affected by the stress and the long-distance accuracy of the low-temperature polysilicon is greatly affected so it also affects the post process.

### SUMMARY

For solving the technical problem above, the present disclosure provides an interlayer-dielectric (ILD) layer, a manufacturing method thereof, and a liquid crystal display panel. The ILD layer has better elasticity and stability and bears smaller stress so it does not damage the film to form the broken film or peeling of the film and reduces influence on the long-distance accuracy of the low-temperature polysilicon.

The present disclosure provides the manufacturing method including the steps of:

S1, sequentially depositing a first SiNx layer having low refractive index and a second SiNx layer having high refractive index on a substrate, wherein the range of the low refractive index is 1.7˜1.87, the range of the high refractive index is 1.91˜1.93, and x [symbol] 1.

S2, depositing a SiOy layer on the second SiNx layer, wherein the refractive index range of the SiOy layer is 1.4˜1.5, and y [symbol] 1.

Before the step S1, preferably, it further includes steps of

S10, depositing a third SiNx layer having high refractive index on the substrate.

The first SiNx layer is above the third SiNx layer. The thickness range of the first SiNx layer, the second SiNx layer, or the third SiNx layer is 800 Å˜1200 Å. The total thickness range of the first SiNx layer, the second SiNx layer, and the third SiNx layer is 2700 Å˜3300 Å.

Preferably, the thickness range of the first SiNx layer or the second SiNx layer is 1200 Å˜1800 Å. The total thickness range of the first SiNx layer and the second SiNx layer is 2700 Å˜3300 Å.

The thickness range of the SiOy layer is 2700 Å˜3300 Å.

Preferably, the step S1 includes:

S11, dissociating a first film-forming gas containing the S1 element and the N element and forming the first SiNx layer by the chemical vapor deposition (CVD) method.

S12, dissociating a second film-forming gas containing the S1 element and the N element and forming the second SiNx layer by the CVD method.

The step S10 specifically includes dissociating a third film-forming gas containing the S1 element and the N element and forming the third SiNx layer by the CVD method.

Preferably, the first film-forming gas includes NH and/or N, and SiH.

The step S11 specifically includes:

S111, filling a CVD reactor with the first film-forming gas, and setting a distance between the upper and lower electrodes for generating an alternating electric field and an alternating electric field value. The range of the distance between the upper and lower electrodes is 50 nm˜150 nm.

S112, dissociating the first film-forming gas by the alternating electric field and depositing the dissociated first film-forming gas on the substrate to form the SiNx layer to be measured. It executes a step S113 then.

S113, measuring the refractive index of the SiNx layer and determining whether the refractive index of the SiNx layer is the low refractive index. If so, the SiNx film to be measured is taken as the first SiNx layer, and if not, it executes a step S114.

S114, if the refractive index of the SiNx film to be measured is greater than the low refractive index, the residual gas is discharged and the first film-forming gas is refilled into the CVD reactor to reduce ratio of the NH occupied in the first film-forming gas. Or reducing the density of the first film-forming gas in the CVD reactor or increasing the alternating electric field value is adopted. It is to execute the step S112 again until the refractive index of the SiNx film to be measured Is the low refractive index. The SiNx film to be measured is adopted as the first SiNx layer.

If the refractive index of the SiNx film to be measured is smaller than the low refractive index, the residual gas is discharged and the first film-forming gas is refilled into the CVD reactor to increase ratio of the NH occupied in the first film-forming gas. Or increasing the density of the first film-forming gas in the CVD reactor or reducing the alternating electric field value is adopted. It is to execute the step S112 again until the refractive index of the SiNx film to be measured Is the low refractive index. The SiNx film to be measured is adopted as the first SiNx layer.

Preferably, the second film-forming gas includes NH and/or N, and SiH.

The step S12 specifically includes:

S121, filling the CVD reactor with the second film-forming gas, and setting a distance between the upper and lower electrodes for generating the alternating electric field and the alternating electric field value. The range of the distance between the upper and lower electrodes is 50 nm˜150 nm.

S122, dissociating the second film-forming gas by the alternating electric field and depositing the dissociated second film-forming gas on the substrate to form the SiNx layer to be measured. It executes a step S123 then.

S123, measuring the refractive index of the SiNx layer and determining whether the refractive index of the SiNx layer is the high refractive index. If so, the SiNx film to be measured is taken as the second SiNx layer, and if not, it executes a step S124.

S124, if the refractive index of the SiNx film to be measured is greater than the high refractive index, the residual gas is discharged and the second film-forming gas is refilled into the CVD reactor to reduce ratio of the NH occupied in the second film-forming gas. Or reducing the density of the second film-forming gas in the CVD reactor or increasing the alternating electric field value is adopted. It is to execute the step S122 again until the refractive index of the SiNx film to be measured is the high refractive index. The SiNx film to be measured is adopted as the second SiNx layer.

If the refractive index of the SiNx film to be measured is smaller than the high refractive index, the residual gas is discharged and the second film-forming gas is refilled into the CVD reactor to increase ratio of the NH occupied in the second film-forming gas. Or increasing the density of the second film-forming gas in the CVD reactor or reducing the alternating electric field value is adopted. It is to execute the step S122 again until the refractive index of the SiNx film to be measured Is the high refractive index. The SiNx film to be measured is adopted as the second SiNx layer.

Preferably, the third film-forming gas includes NH and/or N, and SiH.

The step S10 specifically includes:

S101, filling the CVD reactor with the third film-forming gas, and setting a distance between the upper and lower electrodes for generating the alternating electric field and the alternating electric field value. The range of the distance between the upper and lower electrodes is 50 nm˜150 nm.

S102, dissociating the third film-forming gas by the alternating electric field and depositing the dissociated third film-forming gas on the substrate to form the SiNx layer to be measured. It executes a step S103 then.

S103, measuring the refractive index of the SiNx layer and determining whether the refractive index of the SiNx layer is the low refractive index. If so, the SiNx film to be measured is taken as the third SiNx layer, and if not, it executes a step S104.

S104, if the refractive index of the SiNx film to be measured is greater than the low refractive index, the residual gas is discharged and the third film-forming gas is refilled into the CVD reactor to reduce ratio of the NH occupied in the third film-forming gas. Or reducing the density of the third film-forming gas in the CVD reactor or increasing the alternating electric field value is adopted. It is to execute the step S102 again until the refractive index of the SiNx film to be measured is the low refractive index. The SiNx film to be measured is adopted as the third SiNx layer.

If the refractive index of the SiNx film to be measured is smaller than the low refractive index, the residual gas is discharged and the third film-forming gas is refilled into the CVD reactor to increase ratio of the NH occupied in the second film-forming gas. Or increasing the density of the second film-forming gas in the CVD reactor or reducing the alternating electric field value is adopted. It is to execute the step S102 again until the refractive index of the SiNx film to be measured Is the low refractive index. The SiNx film to be measured is adopted as the third SiNx layer.

The present disclosure further provides an ILD layer including a first SiNx layer, a second SiNx layer, and a SiOy layer.

The second SiNx layer is above the first SiNx layer and the SiOy layer is above the second SiNx layer.

The range of the refractive index of the first SiNx layer is 1.7˜1.87 and the range of the refractive index of the second SiNx layer is 1.91˜1.93. The range of the refractive index of the SiOy layer is 1.4˜1.5, and x≥1, y≥1.

Preferably, the ILD layer further includes a third SiNx layer located under the first SiNx layer 10. The range of the refractive index of the third SiNx layer is 1.91˜1.93.

The present disclosure further provides a liquid crystal display (LCD) panel, including a substrate, a low-temperature polysilicon layer, and an ILD layer.

The low-temperature polysilicon layer is above the substrate and the ILD layer is above the low-temperature polysilicon layer

The ILD layer includes a first SiNx layer, a second SiNx layer, and a SiOy layer.

The second SiNx layer is above the first SiNx layer and the SiOy layer is above the second SiNx layer.

The range of the refractive index of the first SiNx layer is 1.7˜1.87 and the range of the refractive index of the second SiNx layer is 1.91˜1.93. The range of the refractive index of the SiOy layer is 1.4˜1.5, and x≥1, y≥1.

Preferably, the ILD layer further includes a third SiNx layer located under the first SiNx layer 10. The range of the refractive index of the third SiNx layer is 1.91˜1.93.

The present disclosure has beneficial effect below. The ILD layer includes the first SiNx layer having low refractive index which ensures better elasticity and stability of the film. The first SiNx layer having low refractive index has better elasticity so it is hard to generate bubbles between the first SiNx layer and the adjacent film layer and it enhances the stability of the device. In addition, the first SiNx layer has lower refractive index and bears smaller stress so it does not damage the film to form the broken film or peeling of the film. Furthermore, the first SiNx layer accepts smaller stress influence so it reduces contraction of the ILD layer and influence on the long-distance accuracy of the low-temperature polysilicon (e.g. TTP problem). In the post process, it improves the alignment accuracy when the array circuit on the ILD layer aligns with the finger alignment mark on the filter, and the paste accuracy of a thin film transistor (TFT) array circuit and the finger alignment mark on the filter.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a flow chart of a manufacturing method of an interlayer-dielectric (ILD) layer in accordance with an embodiment of the present disclosure.

FIG. 2 is a schematic view of an interlayer-dielectric (ILD) layer in accordance with an embodiment of the present disclosure.

FIG. 3 is a schematic view of an interlayer-dielectric (ILD) layer in accordance with another embodiment of the present disclosure.

FIG. 4 is a schematic view of a liquid crystal display panel in accordance with an embodiment of the present disclosure.

### DETAILED DESCRIPTION OF PREFERRED EMBODIMENTS

The specific structural and functional details disclosed herein are only representative and are intended for describing exemplary embodiments of the disclosure. However, the disclosure can be embodied in many forms of substitution, and should not be interpreted as merely limited to the embodiments described herein.

In the description of the disclosure, terms such as “center”, “transverse”, “above”, “below”, “left”, “right”, “vertical”, “horizontal”, “top”, “bottom”, “inside”, “outside”, etc. for indicating orientations or positional relationships refer to orientations or positional relationships as shown in the drawings; the terms are for the purpose of illustrating the disclosure and simplifying the description rather than indicating or implying the device or element must have a certain orientation and be structured or operated by the certain orientation, and therefore cannot be regarded as limitation with respect to the disclosure. Moreover, terms such as “first” and “second” are merely for the purpose of illustration and cannot be understood as indicating or implying the relative importance or implicitly indicating the number of the technical feature. Therefore, features defined by “first” and “second” can explicitly or implicitly include one or more the features. In the description of the disclosure, unless otherwise indicated, the meaning of “plural” is two or more than two. In addition, the term “comprise” and any variations thereof are meant to cover a non-exclusive inclusion.

In the description of the disclosure, is should be noted that, unless otherwise clearly stated and limited, terms “mounted”, “connected with” and “connected to” should be understood broadly, for instance, can be a fixed connection, a detachable connection or an integral connection; can be a mechanical connection, can also be an electrical connection; can be a direct connection, can also be an indirect connection by an intermediary, can be an internal communication of two elements. A person skilled in the art can understand concrete meanings of the terms in the disclosure as per specific circumstances.

The terms used herein are only for illustrating concrete embodiments rather than limiting the exemplary embodiments. Unless otherwise indicated in the content, singular forms “a” and “an” also include plural. Moreover, the terms “comprise” and/or “include” define the existence of described features, integers, steps, operations, units and/or components, but do not exclude the existence or addition of one or more other features, integers, steps, operations, units, components and/or combinations thereof.

The disclosure will be further described in detail with reference to accompanying drawings and preferred embodiments as follows.

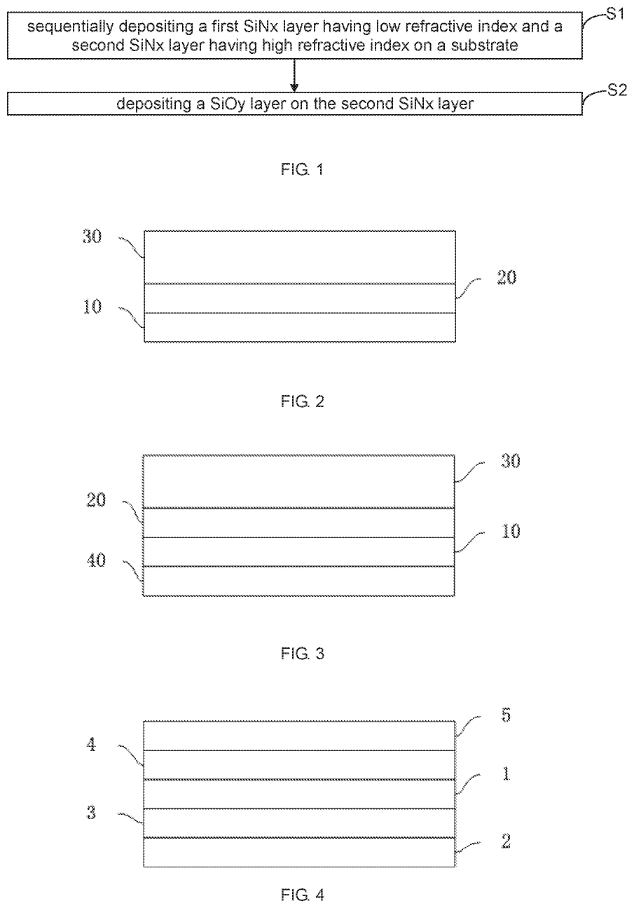

The present disclosure provides a manufacturing method of an interlayer-dielectric (ILD) layer, as shown in FIG. 1. The manufacturing method includes the steps of:

S1, sequentially depositing a first SiNx layer having low refractive index and a second SiNx layer having high refractive index on a substrate. The range of the low refractive index is 1.7˜1.87, the range of the high refractive index is 1.91˜1.93, and x [symbol] 1. The substrate has the finished preprocess. There is a low-temperature polysilicon layer on the substrate. SiNx can be SiN.

S2, depositing a SiOy layer on the second SiNx layer. The refractive index range of the SiOy layer is 1.4˜1.5, and y [symbol] 1. SiOy can be SiO.

The ILD layer includes the first SiNx layer having low refractive index which ensures better elasticity and stability of the film. The first SiNx layer having low refractive index has better elasticity so it is hard to generate bubbles between the first SiNx layer and the adjacent film layer and it enhances the stability of the device.

In addition, the first SiNx layer has lower refractive index and bears smaller stress so it does not damage the film to form the broken film or peeling of the film. Furthermore, the first SiNx layer accepts smaller stress influence so it reduces contraction of the ILD layer and influence on the long-distance accuracy of the low-temperature polysilicon (e.g. TTP problem). In the post process, it improves the alignment accuracy when the array circuit on the ILD layer aligns with the finger alignment mark on the filter, and the paste accuracy of a thin film transistor (TFT) array circuit and the finger alignment mark on the filter.

Before the step S1, it further includes steps of:

S10, depositing a third SiNx layer having high refractive index on the substrate. The first SiNx layer is above the third SiNx layer. The thickness range of the first SiNx layer, the second SiNx layer, or the third SiNx layer is all 800 Å˜1200 Å. Preferably, the thicknesses of the first SiNx layer, the second SiNx layer, or the third SiNx layer is 1000 Å. The total thickness range of the first SiNx layer, the second SiNx layer, and the third SiNx layer is 2700 Å˜3300 Å. Preferably, the total thicknesses of the first SiNx layer, the second SiNx layer, and the third SiNx layer is 3000 Å.

After forming the low-temperature polysilicon layer on the substrate in the preprocess, the third SiNx layer having high refractive index directly contacts the low-temperature polysilicon layer. In the high-temperature process, when the third SiNx layer releases hydrogen, the low-temperature polysilicon layer can fully utilize the hydrogen from the third SiNx layer to perform hydrogenation treatment so the low-temperature polysilicon layer has stronger hydrogen-supplement effect.

Further, when there is no the third SiNx layer deposited on the substrate, the thickness range of the first SiNx layer or the second SiNx layer is 1200 Å˜1800 Å. Preferably, the thicknesses of the first SiNx layer or the second SiNx layer is both 1000 Å. The total thickness range of the first SiNx layer and the second SiNx layer is 2700 Å˜3300 Å. Preferably, the total thicknesses of the first SiNx layer and the second SiNx layer is 3000 Å. The thickness range of the SiOy layer is 2700 Å˜3300 Å. Preferably, the thicknesses of the SiOy layer is 3000 Å.

Further, the step S1 includes:

S11, dissociating a first film-forming gas containing the S1 element and the N element and forming the first SiNx layer by the chemical vapor deposition (CVD) method.

S12, dissociating a second film-forming gas containing the S1 element and the N element and forming the second SiNx layer by the CVD method.

The step S10 specifically includes dissociating a third film-forming gas containing the S1 element and the N element and forming the third SiNx layer by the CVD method.

Further, the first film-forming gas includes NH (ammonia) and/or N (nitrogen), and SiH (silane gas).

The step S11 specifically includes:

S111, filling a CVD reactor with the first film-forming gas, and setting a distance between the upper and lower electrodes for generating an alternating electric field and an alternating electric field value. The range of the distance between the upper and lower electrodes is 50 nm˜150 nm. Preferably, the range of the power transmitted to the upper and lower electrodes to produce alternating electric field is 5000 W˜20000 W.

S112, dissociating the first film-forming gas by the alternating electric field and depositing the dissociated first film-forming gas on the substrate to form the SiNx layer to be measured. It executes a step S113 then.

S113, measuring the refractive index of the SiNx layer and determining whether the refractive index of the SiNx layer is the low refractive index. If so, the SiNx film to be measured is taken as the first SiNx layer, and if not, it executes a step S114.

S114, if the refractive index of the SiNx film to be measured is greater than the low refractive index, the residual gas is discharged and the first film-forming gas is refilled into the CVD reactor to reduce ratio of the NH occupied in the first film-forming gas. Or reducing the density of the first film-forming gas in the CVD reactor or increasing the alternating electric field value is adopted. It is to reselect one substrate as the substrate in the step S112 and execute the step S112 again until the refractive index of the SiNx film to be measured Is the low refractive index. The SiNx film to be measured is adopted as the first SiNx layer.

If the refractive index of the SiNx film to be measured is smaller than the low refractive index, the residual gas is discharged and the first film-forming gas is refilled into the CVD reactor to increase ratio of the NH occupied in the first film-forming gas. Or increasing the density of the first film-forming gas in the CVD reactor or reducing the alternating electric field value is adopted. It is to reselect one substrate as the substrate in the step S112 and execute the step S112 again until the refractive index of the SiNx film to be measured Is the low refractive index. The SiNx film to be measured is adopted as the first SiNx layer.

The reaction between NH, N and SiH is executed to obtain the SiNx film having hydrogen.

The refractive index of the SiNx film can be analyzed and measured according to the reflection and refraction spectra of the film, and the measurement can be performed according to the film thickness measuring apparatus as well. Reducing the density of the first film-forming gas in the CVD reactor can be achieved by increasing the distance between the upper and lower electrodes. On the other hand, reducing the distance between the upper and lower electrodes can increase the density of the first film-forming gas in the CVD reactor Density. The distance between the upper and lower electrodes is adjusted by the film forming apparatus.

The refractive index of SiNx film is almost direct proportional to the ratio of NH occupied in the film-forming gas. Thus, reducing the ratio of NH occupied in the film-forming gas can reduce the refractive index of SiNx film. On the other hand, increasing the ratio of NH occupied in the gas can increase the refractive index of the SiNx film.

Increasing the alternating electric field value, that is, increasing the alternating electric field, can accelerate the dissociation of the film-forming gas so the dissociated film-forming gas rapidly forms the SiNx layer, and there is no sufficient time to closely arrange each particle of the film. Thus, the interval among each particle of the SiNx film layer is increased, the film is loosen, and the refractive index of the SiNx film is reduced. On the other hand, reducing the value of the alternating electric field can slow down the dissociation of the film-forming gas and slow down the dissociation of the film-forming gas to form the SiNx layer so there is sufficient time to closely arrange each particle of the film, and finally the refractive index of the SiNx film is increased.

Further, the second film-forming gas includes NH and/or N, and SiH.

The step S12 specifically includes:

S121, filling the CVD reactor with the second film-forming gas, and setting a distance between the upper and lower electrodes for generating the alternating electric field and the alternating electric field value. The range of the distance between the upper and lower electrodes is 50 nm˜150 nm. Preferably, the range of the power transmitted to the upper and lower electrodes to produce the alternating electric field is 5000 W˜20000 W.

S122, dissociating the second film-forming gas by the alternating electric field and depositing the dissociated second film-forming gas on the substrate to form the SiNx layer to be measured. It executes a step S123 then.

S123, measuring the refractive index of the SiNx layer and determining whether the refractive index of the SiNx layer is the high refractive index. If so, the SiNx film to be measured is taken as the second SiNx layer, and if not, it executes a step S124.

S124, if the refractive index of the SiNx film to be measured is greater than the high refractive index, the residual gas is discharged and the second film-forming gas is refilled into the CVD reactor to reduce ratio of the NH occupied in the second film-forming gas. Or reducing the density of the second film-forming gas in the CVD reactor or increasing the alternating electric field value is adopted. It is to reselect one substrate as the substrate in the step S122 and execute the step S122 again until the refractive index of the SiNx film to be measured is the high refractive index. The SiNx film to be measured is adopted as the second SiNx layer.

If the refractive index of the SiNx film to be measured is smaller than the high refractive index, the residual gas is discharged and the second film-forming gas is refilled into the CVD reactor to increase ratio of the NH occupied in the second film-forming gas. Or increasing the density of the second film-forming gas in the CVD reactor or reducing the alternating electric field value is adopted. It is to reselect one substrate as the substrate in the step S122 and execute the step S122 again until the refractive index of the SiNx film to be measured Is the high refractive index. The SiNx film to be measured is adopted as the second SiNx layer.

Further, the third film-forming gas includes NH and/or N, and SiH.

The step S10 specifically includes:

S101, filling the CVD reactor with the third film-forming gas, and setting a distance between the upper and lower electrodes for generating the alternating electric field and the alternating electric field value. The range of the distance between the upper and lower electrodes is 50 nm˜150 nm. Preferably, the range of the power transmitted to the upper and lower electrodes to produce the alternating electric field is 5000 W˜20000 W.

S102, dissociating the third film-forming gas by the alternating electric field and depositing the dissociated third film-forming gas on the substrate to form the SiNx layer to be measured. It executes a step S103 then.

S103, measuring the refractive index of the SiNx layer and determining whether the refractive index of the SiNx layer is the low refractive index. If so, the SiNx film to be measured is taken as the third SiNx layer, and if not, it executes a step S104.

S104, if the refractive index of the SiNx film to be measured is greater than the low refractive index, the residual gas is discharged and the third film-forming gas is refilled into the CVD reactor to reduce ratio of the NH occupied in the third film-forming gas. Or reducing the density of the third film-forming gas in the CVD reactor or increasing the alternating electric field value is adopted. It is to reselect one substrate as the substrate in the step S102 and execute the step S102 again until the refractive index of the SiNx film to be measured is the low refractive index. The SiNx film to be measured is adopted as the third SiNx layer.

If the refractive index of the SiNx film to be measured is smaller than the low refractive index, the residual gas is discharged and the third film-forming gas is refilled into the CVD reactor to increase ratio of the NH occupied in the second film-forming gas. Or increasing the density of the second film-forming gas in the CVD reactor or reducing the alternating electric field value is adopted. It is to reselect one substrate as the substrate in the step S102 and execute the step S102 again until the refractive index of the SiNx film to be measured Is the low refractive index. The SiNx film to be measured is adopted as the third SiNx layer.

Preferably, the step S2 includes dissociating a forth film-forming gas containing the S1 element and the O element and forming the SiOy layer by the CVD method. The forth film-forming gas is a mixing gas containing SiH and nitrogen oxide gas. The nitrogen oxide gas can be NO.

The present disclosure further provides an ILD layer, as shown in FIG. 2. The ILD layer includes a first SiNx layer 10, a second SiNx layer 20, and a SiOy layer 30.

The second SiNx layer 20 is above the first SiNx layer 10 and the SiOy layer 30 is above the second SiNx layer 20.

The range of the refractive index of the first SiNx layer 10 is 1.7˜1.87 which represents the low refractive index, and the range of the refractive index of the second SiNx layer 20 is 1.91˜1.93 which represents the high refractive index. The range of the refractive index of the SiOy layer 30 is 1.4˜1.5, and x [symbol] 1, y [symbol] 1.

Further, referring to FIG. 3, the ILD layer includes a third SiNx layer 40 located under the first SiNx layer 10. That is, the third SiNx layer 40 is between the first SiNx layer 10 and a substrate. The range of the refractive index of the third SiNx layer 40 is 1.91˜1.93.

The present disclosure further provides a liquid crystal display (LCD) panel, as shown in FIG. 4. The LCD panel includes the substrate 2, a low-temperature polysilicon layer 3, and the ILD layer 1 above. The low-temperature polysilicon layer 3 is above the substrate 2 and the ILD layer 1 is above the low-temperature polysilicon layer 3.

Preferably, the LCD panel further includes a thin film transistor (TFT) array circuit 4 and a filter 5. The TFT array circuit 4 is above the ILD layer 1 and the filter 5 is above the TFT array circuit 4.

In summary, the ILD layer 1 and the manufacturing method thereof provided by the present disclosure have better elasticity and stability. In addition, the first SiNx layer 10 has lower refractive index and bears smaller stress so it does not damage the film to form the broken film or peeling of the film. Furthermore, the first SiNx layer 10 accepts smaller stress influence so it reduces contraction of the ILD layer 1 and influence on the long-distance accuracy of the low-temperature polysilicon. In the post process, it improves the alignment accuracy when the TFT array circuit 4 on the ILD layer 1 aligns with the finger alignment mark on the filter 5.

Further, the third SiNx layer 40 having the high refractive index can ensure that the low-temperature polysilicon layer 4 directly contacting the third SiNx layer 40 has stronger hydrogen-supplement effect.

It is noted that it expands dimension of the layer and the region for clear in the figures. It is understood that each layer is not limited in one element and can include multiple elements. In addition, it is understood that when the element or the layer is on “one side” of another element or another layer, it can be on other elements directly or exist at the middle layer.

The foregoing contents are detailed description of the disclosure in conjunction with specific preferred embodiments and concrete embodiments of the disclosure are not limited to these description. For the person skilled in the art of the disclosure, without departing from the concept of the disclosure, simple deductions or substitutions can be made and should be included in the protection scope of the application.

What is claimed is:

1. A method of manufacturing an interlayer-dielectric (ILD) layer, comprising steps of:
sequentially depositing a first SiNx layer comprising low refractive index and a second SiNx layer comprising high refractive index on a substrate, wherein a range of the low refractive index is 1.7˜1.87, a range of the high refractive index is 1.91˜1.93, and x [symbol] 1; and
depositing a SiOy layer on the second SiNx layer, wherein a refractive index range of the SiOy layer is 1.4˜1.5, and y [symbol] 1.

2. The method of claim 1, before the step of sequentially depositing the first SiNx layer and the second SiNx layer, further comprising:
depositing a third SiNx layer comprising high refractive index on the substrate, wherein the first SiNx layer is above the third SiNx layer, a thickness range of the first SiNx layer, the second SiNx layer, or the third SiNx layer is 800 Å˜1200 Å, and a total thickness range of the first SiNx layer, the second SiNx layer, and the third SiNx layer is 2700 Å˜3300 Å.

3. The method of claim 1, wherein a thickness range of the first SiNx layer or the second SiNx layer is 1200 Å˜1800 Å, and a total thickness range of the first SiNx layer and the second SiNx layer is 2700 Å˜3300 Å.

4. The method of claim 1, wherein the step of sequentially depositing the first SiNx layer and the second SiNx layer comprises:
dissociating a first film-forming gas comprising a S1 element and a N element and forming the first SiNx layer by the chemical vapor deposition (CVD) method; and
dissociating a second film-forming gas comprising the S1 element and the N element and forming the second SiNx layer by the CVD method; and
dissociating a third film-forming gas comprising the S1 element and the N element and forming a third SiNx layer by the CVD method.

5. The method of claim 4, wherein the first film-forming gas comprises NH and/or N, and SiH; and the step of dissociating the first film-forming gas comprises:
filling a CVD reactor with the first film-forming gas and setting a distance between the upper and lower electrodes for generating an alternating electric field and an alternating electric field value, wherein a range of the distance between the upper and lower electrodes is 50 nm˜150 nm;
dissociating the first film-forming gas by the alternating electric field and depositing the dissociated first film-forming gas on the substrate to form the SiNx layer to be measured;
measuring a refractive index of the SiNx layer and determining whether the refractive index of the SiNx layer is the low refractive index, wherein If so, the SiNx film to be measured is taken as the first SiNx layer, and if not, it executes a next step; and
discharging a residual gas and refilling the first film-forming gas into the CVD reactor to reduce ratio of the NH occupied in the first film-forming gas if the refractive index of the SiNx film to be measured is greater than the low refractive index, or reducing the density of the first film-forming gas in the CVD reactor or increasing the alternating electric field value,
wherein it is to execute the step of dissociating the first film-forming gas again until the refractive index of the SiNx film to be measured Is the low refractive index and the SiNx film to be measured is adopted as the first SiNx layer,
wherein if the refractive index of the SiNx film to be measured is smaller than the low refractive index, the residual gas is discharged and the first film-forming gas is refilled into the CVD reactor to increase ratio of the NH occupied in the first film-forming gas, or increasing the density of the first film-forming gas in the CVD reactor or reducing the alternating electric field value is adopted and it is to execute the step of dissociating the first film-forming gas again until the refractive index of the SiNx film to be measured Is the low refractive index and the SiNx film to be measured is adopted as the first SiNx layer.

6. The method of claim 4, the second film-forming gas comprises NH and/or N, and SiH; and the step of dissociating the second film-forming gas comprises:
filling the CVD reactor with the second film-forming gas and setting a distance between the upper and lower electrodes for generating the alternating electric field and the alternating electric field value, wherein a range of the distance between the upper and lower electrodes is 50 nm˜150 nm;
dissociating the second film-forming gas by the alternating electric field and depositing the dissociated second film-forming gas on the substrate to form the SiNx layer to be measured;
measuring the refractive index of the SiNx layer and determining whether the refractive index of the SiNx layer is the high refractive index, wherein If so, the SiNx film to be measured is taken as the second SiNx layer, and if not, it executes a next step; and
discharging a residual gas and refilling the second film-forming gas into the CVD reactor to reduce ratio of the NH occupied in the second film-forming gas if the refractive index of the SiNx film to be measured is greater than the high refractive index, or reducing the density of the second film-forming gas in the CVD reactor or increasing the alternating electric field value,
wherein it is to execute the step of dissociating the second film-forming gas again until the refractive index of the SiNx film to be measured is the high refractive index, and the SiNx film to be measured is adopted as the second SiNx layer,
wherein if the refractive index of the SiNx film to be measured is smaller than the high refractive index, the residual gas is discharged and the second film-forming gas is refilled into the CVD reactor to increase ratio of the NH occupied in the second film-forming gas, or increasing the density of the second film-forming gas in the CVD reactor or reducing the alternating electric field value is adopted and it is to execute the step of dissociating the second film-forming gas again until the refractive index of the SiNx film to be measured Is the high refractive index and the SiNx film to be measured is adopted as the second SiNx layer.

7. The method of claim 4, wherein the third film-forming gas comprises NH and/or N, and SiH; and the step of dissociating the third film-forming gas comprises:
filling the CVD reactor with the third film-forming gas and setting a distance between the upper and lower electrodes for generating the alternating electric field and the alternating electric field value, wherein a range of the distance between the upper and lower electrodes is 50 nm˜150 nm;
dissociating the third film-forming gas by the alternating electric field and depositing the dissociated second film-forming gas on the substrate to form the SiNx layer to be measured;
measuring the refractive index of the SiNx layer and determining whether the refractive index of the SiNx layer is the high refractive index, wherein If so, the SiNx film to be measured is taken as the second SiNx layer, and if not, it executes a next step; and
discharging a residual gas and refilling the second film-forming gas into the CVD reactor to reduce ratio of the NH occupied in the third film-forming gas if the refractive index of the SiNx film to be measured is greater than the low refractive index, or reducing the density of the third film-forming gas in the CVD reactor or increasing the alternating electric field value,
wherein it is to execute the step of dissociating the third film-forming gas again until the refractive index of the SiNx film to be measured is the low refractive index, and the SiNx film to be measured is adopted as the third SiNx layer,
wherein if the refractive index of the SiNx film to be measured is smaller than the low refractive index, the residual gas is discharged and the third film-forming gas is refilled into the CVD reactor to increase ratio of the NH occupied in the second film-forming gas, or increasing the density of the third film-forming gas in the CVD reactor or reducing the alternating electric field value is adopted and it is to execute the step of dissociating the third film-forming gas again until the refractive index of the SiNx film to be measured Is the high refractive index and the SiNx film to be measured is adopted as the third SiNx layer.

8. An interlayer-dielectric (ILD) layer, comprising:
a first SiNx layer;
a second SiNx layer; and
a SiOy layer,
wherein the second SiNx layer is above the first SiNx layer and the SiOy layer is above the second SiNx layer, and
a range of the refractive index of the first SiNx layer is 1.7˜1.87, a range of the refractive index of the second SiNx layer is 1.91˜1.93, a range of the refractive index of the SiOy layer is 1.4˜1.5, and x [symbol] 1, y [symbol] 1.

9. The ILD layer of claim 8, further comprising a third SiNx layer under the first SiNx layer, wherein a range of the refractive index of the third SiNx layer is 1.91˜1.93.

10. A liquid crystal display (LCD) panel, comprising:
a substrate;
a low-temperature polysilicon layer; and
an interlayer-dielectric (ILD) layer;
wherein the low-temperature polysilicon layer is above the substrate and the ILD layer is above the low-temperature polysilicon layer;
wherein the ILD layer comprises a first SiNx layer, a second SiNx layer, and a SiOy layer, the second SiNx layer is above the first SiNx layer and the SiOy layer is above the second SiNx layer, a range of the refractive index of the first SiNx layer is 1.7˜1.87, a range of the refractive index of the second SiNx layer is 1.91˜1.93, a range of the refractive index of the SiOy layer is 1.4˜1.5, and x [symbol] 1, y [symbol] 1.

11. The LCD panel of claim 10, wherein the ILD layer further comprises a third SiNx layer under the first SiNx layer, wherein a range of the refractive index of the third SiNx layer is 1.91˜1.93.
